(19) United States
(12) Patent Application Publication
(10) Pub. No.: US 2016/0021734 A1
(43) Pub. Date: Jan. 21, 2016

(54) SEMICONDUCTOR DEVICE WITH ACTIVE SHIELDING OF LEADS

(71) Applicants: Sunaina Srivastava, Gurgaon (IN); Raza Imam, Ghaziabad (IN); Gagan Kansal, Gurgaon (IN); Sumit Varshney, Noida (IN)

(72) Inventors: Sunaina Srivastava, Gurgaon (IN); Raza Imam, Ghaziabad (IN); Gagan Kansal, Gurgaon (IN); Sumit Varshney, Noida (IN)

(73) Assignee: Freescale Semiconductor, Inc., Austin, TX (US)

(21) Appl. No.: 14/332,372

(22) Filed: Jul. 15, 2014

(51) Int. Cl. H05K 1/02; H01L 23/552; H01L 23/00; H01L 23/64

(52) U.S. Cl. CPC H05K 1/0216; H01L 23/64; H01L 23/552; H01L 24/48; H01L 2224/4805; H01L 2224/4899

(57) ABSTRACT

A semiconductor device has a multi-wire lead and a die having a multi-site bond pad. A shielding wire and a guarded wire both extend from the multi-wire lead to the multi-site bond pad. The shielding wire (or wires) provide active shielding to the guarded wire by simultaneously transmitting the same signal as the guarded wire between the multi-wire lead the multi-site bond pad.

### BACKGROUND OF THE INVENTION

The present invention relates generally to semiconductor devices and, more particularly, to shielding the leads of semiconductor devices.

Some semiconductor devices have lead frames that include leads, and bond wires that extend between the leads and bonding pads of a die mounted on a paddle or flag of the lead frame. The leads transmit signals, power and ground to/from the die. Two leads that carry signals located near each other may couple to one another. This is referred to as “crosstalk” or “cross-coupling,” where variations in one signal can affect amplitudes of nearby signals.

In order to reduce the coupling between two signals, a ground shield may be provided between the leads. One approach for providing passive, ground shielding is to connect every other lead to ground to avoid coupling. However, this limits the number of leads that may be used to carry signals.

Active shielding is another approach to providing shielding in electronic networks. Active shielding is a shielding technique in which one or more shielding lines transmit signals that are dependent upon the signals transmitted by the guarded line. Capacitive coupling is reduced with active shielding when the shielding lines transmit signals in the same direction as the guarded line and inductive coupling is reduced when the shielding lines transmit signals in the opposite direction as the guarded line. Active shielding is typically implemented using the layouts of one or both of the integrated circuits (dies) or printed circuit boards (PCBs). In low-profile quad flat packages (LQFP), active shielding has not been implemented because conventional LFQP layouts and lead frame arrangements do not allow realization of active shielding. However, without the proper shielding in semiconductor devices, like LQFP devices, unwanted cross-coupling may occur.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

The FIGURE is a simplified top plan view of a part of a semiconductor package made in accordance with an embodiment of the present invention.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components.

In the present invention, shielding structures are provided for semiconductor packages that are able to protect signal leads from experiencing coupling. Instead of providing a (passive) grounded shield, active shielding is provided. In one embodiment, the present invention is a semiconductor device comprising a die having a multi-site bond pad; a multi-wire lead; at least one shielding wire extending from the multi-wire lead to the multi-site bond pad; and a guarded wire extending from the multi-wire lead to the multi-site bond pad.

Another embodiment of the invention is a method of actively shielding a guarded wire on a semiconductor device. The method comprises (a) transmitting a first signal along the guarded wire extending between a multi-wire lead and a die having a multi-site bond pad; and (b) simultaneously transmitting the first signal along at least one shielding wire extending from the multi-wire lead to the multi-site bond pad.

The FIGURE shows a simplified top plan view of a part of a partially assembled semiconductor device 100 made in accordance with an embodiment of the present invention. The semiconductor device 100 shown comprises a die 101 attached to a die flag or paddle 102. The die 101 has bond pads 103 that are electrically connected to leads 104 with bond wires 105.

The die paddle 102 and leads 104 are formed as part of a lead frame. As is known by those of skill in the art, a lead frame is a collection of metal leads and possibly other elements (e.g., ground bars and power bars) that is used in semiconductor packaging. Prior to assembly into a packaged device, a lead frame may have support structures (e.g., a rectangular metal frame) that keep those elements in place. During the assembly process, the support structures may be removed. As used herein, the term “lead frame” may be used to refer to the collection of elements before assembly or after assembly, regardless of the presence or absence of those support structures.

Signals are transmitted between at least some of the leads 104 and the corresponding die bond pads 103 via corresponding bond wires 105. As discussed above, signals can suffer cross-coupling from signals transmitted on bond wires of adjacent leads. In order to prevent cross-coupling from occurring, active shielding of the bond wires 105 is achieved through the use of a multi-wire lead 106 and a multi-site bond pad 107.

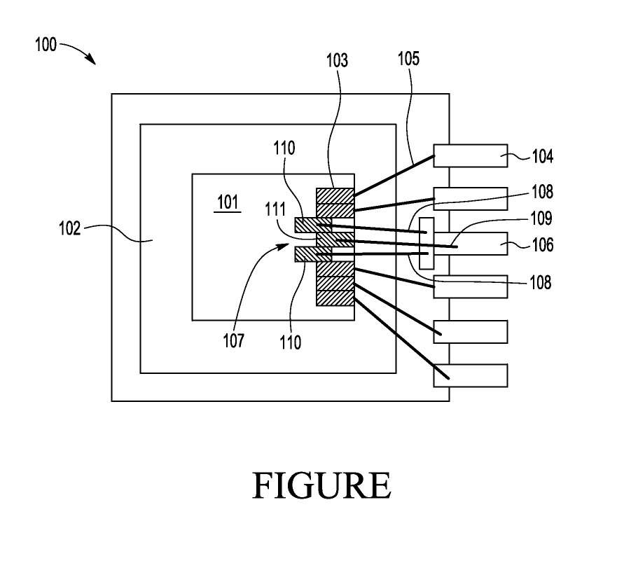

The multi-wire lead 106 can be formed as a unitary lead during formation of the lead frame or alternatively may be part of an overlay assembly that may be placed over an already existing lead frame. In the embodiment shown in FIG. 1, the multi-wire lead 106 is T-shaped. However, it should be understood that a multi-wire lead may be formed or placed on the lead to form a cross or other shape that is capable of having multiple bond wires attached to it. In some embodiments, a conventional (e.g., straight) lead may be capable of accommodating multiple bond wires without modification.

The three bond wires attached to the multi-wire lead 106 shown in the figure are referred to herein as shielding wires 108 and guarded wire 109. The shielding wires 108 are attached on opposite sides of the multi-wire lead 106 and carry the same signal as the guarded wire 109, which is located between the two shielding wires 108. The guarded wire 109 also is attached to the multi-wire lead 106. The shielding wires 108 extend from the multi-wire lead 106 to the die 101 proximate and adjacent to the guarded wire 109 as it extends from the multi-wire lead 106 to the die 101.

The shielding wires 108 take the impact of any potential cross-talk that might otherwise occur between the guarded wire 109 and any signals being transmitted on adjacent bond wires 105. This is active shielding of the guarded wire 109. While two shielding wires 108 are shown in the embodiment disclosed, it should be understood that, in some instances, one shielding wire may be sufficient to prevent cross-talk with an adjacent wire, or in some instances more than two shielding wires may be needed to prevent cross-talk.

The multi-site bond pad 107 has the two shielding wires 108 and the one guarded wire 109 attached to it at two shielding-wire bond-pad sites 110 and one guarded-wire bond-pad site 111, respectively. The two shielding-wire bond-pad sites 110 and one guarded-wire bond-pad site 111 are physically connected to one another without having impedance between any two of them. The multi-site bond pad 107 may be formed during the formation of the die 101 or may be part of an overlay process that modifies an existing die to provide multiple sites for receiving the shielding wires and guarded wire. In the embodiment shown, the shielding-wire bond-pad sites 110 are located on either side of the guarded-wire bond-pad site 111. The same signals are transmitted between (i) the multi-wire lead 106 and (ii) the shielding-wire bond-pad sites 110 and the guarded-wire bond-pad site 111 by way of the shielding wires 108 and the guarded wire 109, respectively.

The shielding wires 108 extending between the multi-site bond pad 107 and the multi-wire lead 106 provide active shielding for the signals transmitted along the guarded wire. The active shielding reduces cross-talk between the guarded wire and adjacent bond wires connected to other leads. Active shielding comes at an increased cost of power consumption. Thus, sufficient current should be provided to the guarded wire to ensure that the transmitted signal is strong enough. The three bond wires electrically shorted to one another carry the electric field in the same direction. Due to the Miller Effect, the capacitance on the guarded wire becomes zero, and the guarded wire is not affected by the adjacent bond wires or the shielding wires. The Miller Effect states that the effective coupling capacitance between two nodes is zero if the transitions at the two nodes occur at the same time and in the same direction.

In semiconductor packages, such as LQFP packages, the active shielding of the present invention is able to provide protection for signals transmitted on guarded wires. Active shielding is able to help protect global clock networks and high-speed networks in semiconductor packages.

Although the invention has been described using relative terms such as “down,” “out,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

It should be understood that the steps of the exemplary methods set forth herein, if any, are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

1. A semiconductor device, comprising:
a die having a multi-site bond pad;
a multi-wire lead;
at least one shielding wire extending from the multi-wire lead to the multi-site bond pad; and
a guarded wire extending from the multi-wire lead to the multi-site bond pad.

2. The semiconductor device of claim 1, wherein the multi-wire lead is “T” shaped.

3. The semiconductor device of claim 2, wherein the at least one shielding wire comprises two shielding wires extending from the multi-wire lead to the multi-site bond pad.

4. The semiconductor device of claim 3, wherein the two shielding wires extend between the multi-wire lead and the multi-site bond pad on opposite sides of the guarded wire.

5. The semiconductor device of claim 1, wherein the multi-site bond pad has at least one shielding-wire bond-pad site and a guarded-wire bond-pad site.

6. The semiconductor device of claim 5, wherein the multi-site bond pad has two shielding-wire bond-pad sites each located on opposite sides of the guarded-wire bond-pad site.

7. The semiconductor device of claim 5, wherein the at least one shielding-wire bond-pad site and the guarded-wire bond-pad site are physically connected to one another without having impedance therebetween.

8. The semiconductor device of claim 1, wherein the semiconductor device is a low-profile quad flat package.

9. A method of actively shielding a guarded wire on a semiconductor device, the method comprising:
transmitting a first signal along the guarded wire, which extends between a multi-wire lead and a multi-site bond pad of a die; and
simultaneously transmitting the first signal along at least one shielding wire extending from the multi-wire lead to the multi-site bond pad.

10. The method of claim 9, wherein transmitting step comprises simultaneously transmitting the first signal along two shielding wires extending from the multi-wire lead to the multi-site bond pad on either side of the guarded wire.

11. The method of claim 9, wherein the multi-wire lead is “T” shaped.

12. The method of claim 9, comprising simultaneously transmitting the first signal along at least two shielding wires extending from the multi-wire lead to the multi-site bond pad.

13. The method of claim 12, wherein the two shielding wires extend between the multi-wire lead and the multi-site bond pad on opposite sides of the guarded wire.

14. The method of claim 9, wherein the multi-site bond pad has at least one shielding-wire bond-pad site and a guarded-wire bond-pad site.

15. The method of claim 14, wherein the multi-site bond pad has two shielding-wire bond-pad sites each located on either side of the guarded-wire bond-pad site.

16. The method of claim 14, wherein the at least one shielding-wire bond-pad site and the guarded-wire bond-pad site are physically connected to one another without having impedance therebetween.

17. The method of claim 9, wherein the semiconductor device is a low-profile quad flat package.
